(19) United States
(12) Patent Application Publication
(10) Pub. No.: US 2017/0330971 A1
(43) Pub. Date: Nov. 16, 2017

(54) SEMICONDUCTOR STRUCTURE AND METHOD FOR FORMING THE SAME

(71) Applicant: ZING SEMICONDUCTOR CORPORATION, Shanghai (CN)

(72) Inventor: DEYUAN XIAO, Shanghai (CN)

(21) Appl. No.: 15/271,029

(22) Filed: Sep. 20, 2016

(30) Foreign Application Priority Data
May 13, 2016 (CN) 201610319775.4

(51) Int. Cl. H01L 29/78; H01L 29/66; H01L 29/167; H01L 29/08; H01L 21/428; H01L 21/265

(52) U.S. Cl. CPC H01L 29/7851; H01L 29/66795; H01L 29/66545; H01L 21/265; H01L 29/0847; H01L 21/428; H01L 29/167

(57) ABSTRACT

The present invention relates to a semiconductor structure and a method for forming the same. The method comprises steps of providing a substrate having a dummy gate, forming an elevated semiconductor source/drains epitaxy growing with lower in-situ doping concentration; forming a second elevated semiconductor source/drains epitaxy growing with higher in-situ doping concentration.

### INCORPORATION BY REFERENCE

This application claims priority from China Patent Application No. 201610319775.4, filed on May 13, 2016, the contents of which are hereby incorporated by reference in their entirety for all purposes.

### TECHNICAL FIELD

The present invention relates to a semiconductor manufacturing process, and particularly, relates to a three dimensional (3D) semiconductor device structure and the method of manufacturing it.

### BACKGROUND

As the scaling of strained-Si MOSFETs continues, the performance enhancement may become susceptible to degradation during processing, particularly from ion implantation and thermal processing effects.

More specifically, the ion implant dose under the gate (e.g., associated with the halo and/or extensions implants) increases with scaling. In addition, the damage associated with the source/drain extension regions may comprise a larger portion of the channel as the device is scaled. Ion implantation damage may supply point defects that assist the relaxation of strain or the up-diffusion of species (e.g. Ge) from the underlying layers.

Moreover, residual ion implantation damage remaining after thermal annealing may act as carrier scattering centers. In strained-Si films thermal processing such as i.e. post implantation anneal can cause misfit dislocations, leading to strain relaxation as well as enhanced impurity diffusion, resulting ultimately in decreased carrier mobility.

When compared to planar junctions, junction formation on multi-gate 3-D structures, present additional challenges in achieving conformal doping profiles. More specifically, because of the unidirectional nature of the ion beam and of the shadowing effect at elevated structures (fins), it becomes more and more difficult to achieve a conformal FinFET junction using conventional ion implantation technique.

In addition to that, for very narrow fin structures the amorphization caused by the conventional ion implantation cannot be fully recovered by thermal anneal.

Despite the progress in the art, there is still need for a method for doping strained semiconductor layers or narrow semiconductor structures (e.g. fin structures in FinFET devices) that can replace the conventional ion implantation technique and possibly the subsequent thermal annealing steps, while keeping the device performance un-altered or improving it.

### SUMMARY

The present invention provides a semiconductor device structure and the method of manufacturing it to improve the performance of the 3D semiconductor device.

In order to solve the above-mentioned problems, an object of the present invention is to provide a method of forming a semiconductor structure. The method comprises the steps of providing a substrate with dummy gates; performing a first elevated semiconductor source/drains epitaxy growing with lower in-situ doped doping concentration; and performing a second elevated semiconductor source/drains epitaxy growing with higher in-situ doped doping concentration.

In one embodiment, an optional step of a pulse laser anneal is performed after said second elevated semiconductor source/drains epitaxy growing, wherein a shape of said elevated semiconductor source/drains did not change and were not merged together after said pulse laser anneal.

In one embodiment, wherein said substrate is selected from the group consisting of bulk silicon, silicon-on-insulator (SOI), SixGe1−x (0<x<1) on SOI, SixGe1−x (0<x<1) on Si, bulk Ge, GaAs, InP, InSb, InGaAs, AlGaAs, InAlAs and mixtures thereof.

In one embodiment, wherein said doping comprises N type impurities, and said N type impurities preferably selected from the group consisting of arsine (AsH₃), phosphine (PH₃) and mixtures thereof.

In one embodiment, wherein said doping comprises P type impurities, and said P type impurities is diborane.

In one embodiment, wherein a doping concentration of said first elevated semiconductor source/drains epitaxy growing is 1.0×10¹⁷ cm⁻³˜5×10¹⁸ cm⁻³.

In one embodiment, wherein a doping concentration of said second elevated semiconductor source/drains epitaxy growing is 5.0×10¹⁸ cm⁻³˜2×10¹⁹ cm⁻³.

An object of the present invention is also to provide a semiconductor structure. The semiconductor structure is comprised of a semiconductor substrate with fin type structure; a first elevated semiconductor source/drains with lower doping concentration; and a second elevated semiconductor source/drains with higher doping concentration.

### BRIEF DESCRIPTION OF THE DRAWINGS

Exemplary embodiments will be more readily understood from the following detailed description when read in conjunction with the appended drawing, in which:

FIG. 1 is a flow chart of a fabrication method of a semiconductor device according to one embodiment of the present invention; and

FIGS. 2-4 are cross-sectional views showing process stages of manufacturing a semiconductor device according to one embodiment of the present invention.

### DETAILED DESCRIPTION

The following detailed description in conjunction with the drawings of a vacuum tube nonvolatile memory and fabrication method thereof of the present invention represents the preferred embodiments. It should be understood that the skilled in the art can modify the present invention described herein to achieve advantageous effect of the present invention. Therefore, the following description should be understood as well known for the skilled in the art, but should not be considered as a limitation to the present invention.

For purpose of clarity, not all features of an actual embodiment are described. It may not describe the well-known functions as well as structures in detail to avoid confusion caused by unnecessary details. It should be considered that, in the developments of any actual embodiment, a large number of practice details must be made to achieve the specific goals of the developer, for example, according to the requirements or the constraints of the system or the commercials, one embodiment is changed to another. In addition, it should be considered that such a development effort might be complex and time-consuming, but for a person having ordinary skills in the art is merely routine work.

In the following paragraphs, the accompanying drawings are referred to describe the present invention more specifically by way of example. The advantages and the features of the present invention are more apparent according to the following description and claims.

In this specification, the term “semiconductor” denotes a semiconductor material that includes at least one element from Group III of the Periodic Table of Elements and at least one element from Group V of the Periodic Table of Elements. Typically, the III-V compound semiconductors are binary, ternary or quaternary alloys including III/V elements. Examples of III-V compound semiconductors that can be used in the present invention include, but are not limited to alloys of GaAs, InP, InSb, InGaAs, AlGaAs, InAlAs, InAlAsSb, and InGaAsP. It should be noted that the drawings are in a simplified form with non-precise ratio for the purpose of assistance to conveniently and clearly explain an embodiment of the present invention.

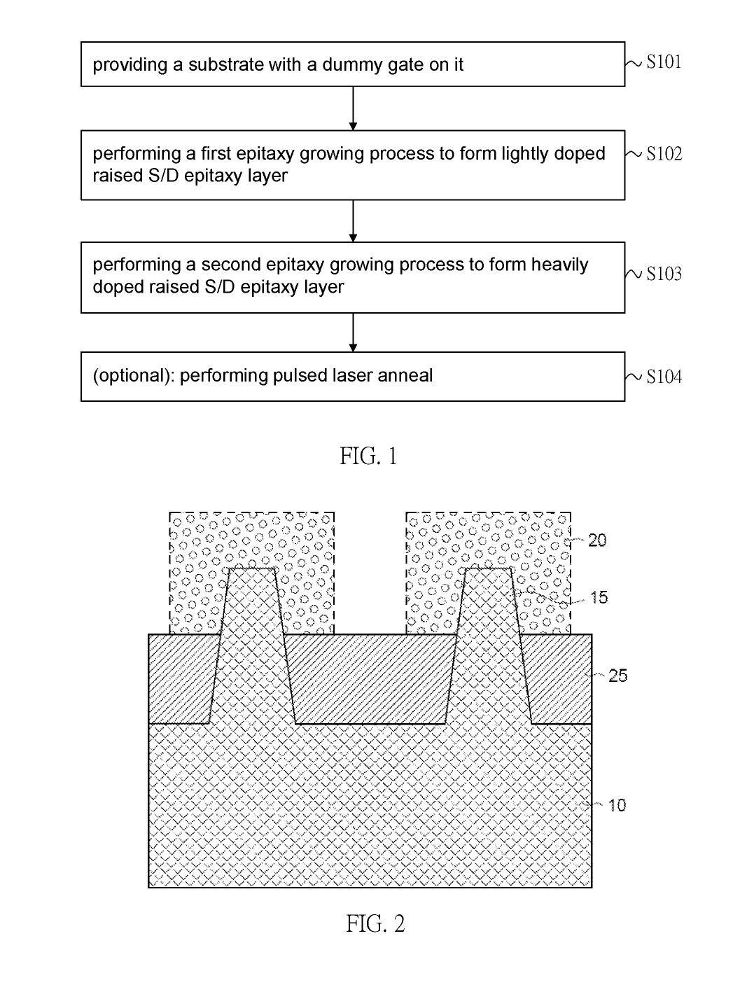

Please refer to FIG. 1, It illustrates a flow chart of manufacturing a non-planar transistor according to an example embodiment of the present invention. The method includes the steps of:

S101: providing a substrate, the substrate includes a channel region and a fin type semiconductor structure; it also has a dummy gate on the fin type semiconductor structure;

S102: performing a first epitaxy growing process to deposit semiconductor material on regions of the fin disposed on opposite sides of the channel region to lightly doped raised source/drains; wherein the first step epitaxy film with lower in-situ doped doping concentration;

S103: performing a second epitaxy growing process to deposit semiconductor material on regions of the fin disposed on opposite sides of the channel region to form heavily doped raised source/drains; wherein the second step epitaxy film with higher in-situ doped doping concentration; and

S104 (optional): performing pulsed laser anneal.

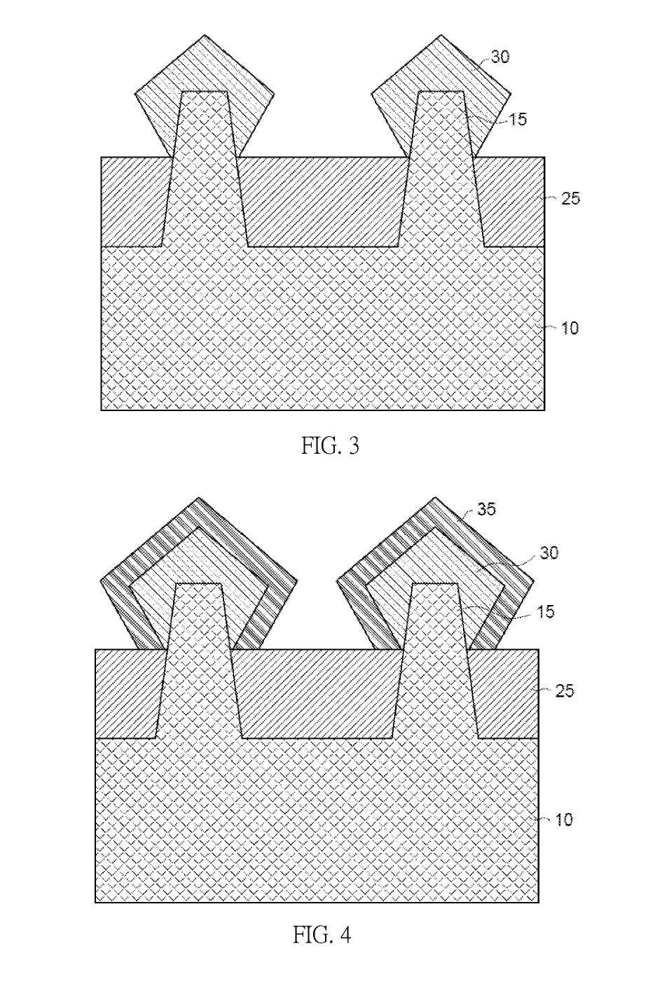

In particular, please refer to the following FIGS. 2-4 for the manufacturing process details. Now, refer to FIG. 2, it illustrates the cross-sectional view after the first step of manufacturing the non-planar transistor according to an example embodiment of the present invention. In step S101, a dummy gate 20 is formed on a substrate 10. In one embodiment, the substrate 10 can be a silicon wafer with a fin type semiconductor 15 and shallow trench isolation (STI) 25 structures ready for raised S/D epitaxy growing process. The dummy gate 20 can be formed by the gate last process well known in the art. In other embodiments, the substrate 10 can also be a silicon on insulator (SOI), SixGe1−x (0<x<1) on SOI, SixGe1−x (0<x<1) on Si, bulk Ge, GaAs, InP, InSb, InGaAs, AlGaAs, InAlAs or mixtures thereof. Thereafter, the typical wafer clean process is performed.

Next, refer to FIG. 3. It illustrates the cross-sectional view after the second step of manufacturing the non-planar transistor according to an example embodiment of the present invention. A first epitaxy growing process is performed on the substrate 10 with dummy gate to deposit semiconductor material on regions of the fin disposed on opposite sides of the channel region to form lightly doped raised source/drains 30; wherein the first step epitaxy film with lower in-situ doped doping concentration, in particular, the first epitaxy growing process is an in-situ gas phase epitaxy growing process. In one embodiment, the first dopants are n-type dopants preferably selected from the group consisting of arsine (AsH₃), phosphine (PH₃) or mixtures thereof. In the other embodiment, the first dopants are p-type dopants preferably selected to be diborane. The preferred doping concentration of the first epitaxy growing process is in the rage of 10¹⁷/cm³ to 5×10¹⁸/cm³.

In one embodiment, the in-situ gas phase epitaxy growing process is performed in the temperature range of 800˜1100° C., for 10-2000 minutes to obtain a thickness of 10-5000 nm epitaxy film of lightly doped raised source/drains 30.

The process parameters such as gas type, reaction temperature and time can be adjusted by the actual requirement to get optima properties of the lightly doped raised source/drains 30.

Next, refer to FIG. 4. It illustrates the cross-sectional view after the third step of manufacturing the non-planar transistor according to an example embodiment of the present invention. A second epitaxy growing process is performed on the substrate 10 with dummy gate to deposit semiconductor material on regions of the fin disposed on opposite sides of the channel region to form heavily doped source/drains 35 on the outside of the raised source/drains 30; wherein the second step epitaxy film with higher in-situ doped doping concentration, in particular, the second epitaxy growing process is an in-situ gas phase epitaxy growing process. In one embodiment, the second dopants are n-type dopants preferably selected from the group consisting of arsine (AsH₃), phosphine (PH₃) or mixtures thereof. Similarly, in another embodiment, the second dopants are p-type dopants preferably selected to be diborane. The preferred doping concentration of the second epitaxy growing process is in the rage of 5×10¹⁸/cm³ to 2×10¹⁹/cm³.

In one embodiment, the in-situ gas phase epitaxy growing process is performed in the temperature range of 800˜1100° C., for 10-2000 minutes to obtain a thickness of 10-5000 nm epitaxy film of heavily doped source/drains 35. The thickness of the heavily doped source/drains 35 is thinner than that of the raised source/drains 30.

Similarly, the process parameters such as gas type, reaction temperature and time can be adjusted by the actual requirement to get optima properties of the heavily doped raised source/drains 35.

Finally, in step 104, an optional pulsed laser anneal is performed in order to fully activated the dopant at the elevated S/D area while the shape of the raised S/D is not changed. In one embodiment, the laser anneal process is performed in the temperature range of 1200˜1400° C. for 0.0001˜10 seconds.

While various embodiments in accordance with the disclosed principles been described above, it should be understood that they are presented by way of example only, and are not limiting. Thus, the breadth and scope of exemplary embodiment(s) should not be limited by any of the above-described embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically, a description of a technology in the “Background” is not to be construed as an admission that technology is prior art to any invention(s) in this disclosure. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings herein.

1. A method of forming a semiconductor structure, comprising the steps of:
providing a substrate with dummy gates;
performing a first elevated semiconductor source/drains epitaxy growing with lower in-situ doped doping concentration;
performing a second elevated semiconductor source/drains epitaxy growing with higher in-situ doped doping concentration; and
performing a pulse laser anneal, wherein a shape of said first and second elevated semiconductor source/drains did not change and not merged together after said pulse laser anneal.

2. (canceled)

3. (canceled)

4. The method of claim 1, wherein said substrate is selected from the group consisting of bulk silicon, silicon-on-insulator (SOI), SixGe1−x (0<x<1) on SOI, SixGe1−x (0<x<1) on Si, bulk Ge, GaAs, InP, InSb, InGaAs, AlGaAs, InAlAs and mixtures thereof.

5. The method of claim 1, wherein said doping of said first and second elevated semiconductor source/drains epitaxy growing comprises N type impurities, and said N type impurities preferably selected from the group consisting of arsine (AsH₃), phosphine (PH₃) and mixtures thereof.

6. The method of claim 1, wherein said doping of said first and second elevated semiconductor source/drains epitaxy growing comprises P type impurities, and said P type impurities is diborane.

7. The method of claim 1, wherein a doping concentration of said first elevated semiconductor source/drains epitaxy growing is 1.0×10¹⁷ cm⁻³˜5×10¹⁸ cm⁻³.

8. The method of claim 1, wherein a doping concentration of said second elevated semiconductor source/drains epitaxy growing is 5.0×10¹⁸ cm⁻³˜2×10¹⁹ cm⁻³.

9. The method of claim 2, wherein said pulse laser anneal is operated at a temperature range of 1200˜1400° C.

10. A semiconductor structure, comprising:
a semiconductor substrate with fin type structure;
a first elevated semiconductor source/drains with lower doping concentration; and
a second elevated semiconductor source/drains with higher doping concentration.
